(19) United States
(12) Patent Application Publication
(10) Pub. No.: US 2024/0304487 A1
(43) Pub. Date: Sep. 12, 2024

(54) SUBSTRATE PROCESSING DEVICE USING MULTI-ZONE HEAT TRANSFER STRUCTURE AND TEMPERATURE CONTROL METHOD

(71) Applicant: Kwangwoon University Industry-Academic Collaboration Foundation, Seoul (KR)

(72) Inventors: Gi Chung KWON, Seongnam-si, Gyeonggi-do (KR); Hee Tae KWON, Bucheon-si, Gyeonggi-do (KR); Ji Hwan KIM, Goyang-si, Gyeonggi-do (KR); In Young BANG, Seoul (KR)

(21) Appl. No.: 18/574,925

(22) PCT Filed: Jun. 30, 2022
(86) PCT No.: PCT/KR2022/009453

§ 371 Date: Dec. 28, 2023

(30) Foreign Application Priority Data
Jul. 2, 2021 (KR) 10-2021-0087370

(51) Int. Cl. H01L 21/683; B23Q 3/15

(52) U.S. Cl. CPC H01L 21/6833; B23Q 3/15

(57) ABSTRACT

Exemplary embodiments of the present invention provide a substrate processing device and a multi-zone temperature control method which block or transfer heat generated between a substrate and an electrostatic chuck and a base structure or between specific structures using the change in pressure of a heat transfer gas by installing a multi-zone heat transfer adjustment structure between a base structure in which a coolant is supplied and the substrate to easily adjust the temperature of the substrate during the process or after the process.

### TECHNICAL FIELD

The technical field of the present invention relates to a substrate processing device and a temperature control method.

### BACKGROUND ART

The contents described in this section merely provide background information on the present exemplary embodiment but do not constitute the related art.

During a semiconductor process such as etching or deposition, a substrate located above an electrostatic chuck (ESC) includes a coolant channel located below the electrostatic chuck to prevent the rising of temperature due to an energy, such as plasma, light, or heater and adjusts a temperature by supplying a coolant to a base structure which is used as a radio frequency (RF) electrode.

As a process difficulty in the existing etching or deposition process is increased, in the base structure located below the electrostatic chuck, a process situation required to form environments of 1) a high temperature of 100° C. or higher, ii) a low temperature of −100° C. or higher and 0° C. or lower, and iii) an extremely low temperature (cryogenic) of −100° C. or lower on the substrate, as needed, occurs.

Even after the process is completed, the temperature of the substrate may be 1) a high temperature of 100° C. or higher, ii) a low temperature of −100° C. or higher and 0° C. or lower, and iii) an extremely low temperature (cryogenic) of −100° C. or lower in some cases. When the substrate at a low temperature of −100° C. or higher and 0° C. or lower or an extremely low temperature (cryogenic) of −100° C. or lower is transported to the outside of a chamber, problems such as condensation or particle adsorption may occur on the substrate due to the water vapor.

When the substrate temperature is changed from the low temperature of −100° C. or higher and 0° C. or lower to an extremely low temperature (cryogenic) of −100° C. or lower or from the extremely low temperature (cryogenic) of −100° C. or lower to the low temperature of −100° C. or higher and 0° C. or lower, it takes longer time to change a temperature of the coolant supplied from the chiller and it is difficult to change the temperature in a wide range from the extremely low temperature (cryogenic) of −100° C. or lower to the temperature of 0° C. or higher. (Patent Document 1) Korean Unexamined Patent Application Publication No. 10-2020-0096145 (published on Aug. 11, 2020) (Patent Document 2) Korean Registered Patent Publication No. 10-2106419 (Apr. 24, 2020)

### DISCLOSURE

### Technical Problem

A main object of exemplary embodiments of the present invention is to block or transfer heat which may be generated between a substrate and an electrostatic chuck and a base structure or between specific structures using the change in pressure of a heat transfer gas by installing a multi-zone heat transfer adjustment structure between a base structure in which a coolant is supplied and the substrate, in a substrate processing device to easily adjust the temperature of the substrate during the process or after the process.

Other and further objects of the present disclosure which are not specifically described can be further considered within the scope easily deduced from the following detailed description and the effect.

### Technical Solution

According to an aspect of the present embodiment, a substrate processing device includes: a chamber, a substrate holder which is located in the chamber and has an electrostatic chuck which fixes a substrate using electrostatic force; a base structure which is located in the chamber and has a channel formed therein; a heat transfer adjustment structure which is located between the substrate holder and the base structure and has a plurality of inner spaces; a substrate gas supply device which is connected to the substrate holder and supplies a substrate gas; a chucking power supply device which is connected to the electrostatic chuck and supplies a chucking power to the electrostatic chuck; a heat transfer gas control device which is connected to the heat transfer adjustment structure and supplies the heat transfer gas; a high frequency power supply device which is connected to the base structure and supplies a high frequency power; and a coolant supply device which is connected to the channel and supplies a coolant.

The substrate holder includes a heat structure which adjusts a temperature of the substrate and the substrate processing device includes a heat power supply device which supplies a heat power to the heat structure.

The heat transfer adjustment structure has a plurality of inner spaces by a top plate, a bottom plate, a side wall, and a separation wall and a heat transfer gas may flow in or out through a gas port which is connected to the top plate, the bottom plate, the side wall, or a combination thereof.

The heat transfer adjustment structure is divided into an inner circle and an outer circle by the separation wall.

The substrate processing device includes a temperature measurement device which is connected to the top plate of the heat transfer adjustment structure to measure a temperature of the top plate, is connected to the bottom plate of the heat transfer adjustment structure to measure a temperature of the bottom plate, and is connected to the base structure to measure a temperature of the base structure.

Coefficients of thermal expansion between the heat transfer adjustment structure and the base structure are set to have a difference within ±50%.

The heat transfer gas control device communicates with the temperature measurement device to control the difference between the temperature of the top plate and the temperature of the bottom plate to be within a predetermined range.

The side surface of the heat transfer adjustment structure is formed to have a curved structure.

The substrate processing device includes a plurality of support columns between the top plate and the bottom plate of the heat transfer adjustment structure.

A bottom surface of the top plate and a top surface of the bottom plate of the heat transfer adjustment structure are formed to have a spike structure.

A bottom surface of the top plate and a top surface of the bottom plate of the heat transfer adjustment structure are formed to have a fin structure.

A bottom surface of the top plate and a top surface of the bottom plate of the heat transfer adjustment structure are formed to have an embossing structure.

The heat transfer gas control device supplies or discharges the heat transfer gas to the heat transfer adjustment structure through a single gas port according to a temporal separation manner.

The heat transfer gas control device supplies or discharges the heat transfer gas to the heat transfer adjustment structure through a plurality of gas ports which are separately installed according to a spatial separation manner.

The heat transfer gas control device adjusts a pressure of the heat transfer gas to control temperature change of the plurality of inner spaces of the heat transfer adjustment structure.

The heat transfer adjustment structure varies a heat transfer amount between the top plate and the bottom plate according to the change of the pressure of the heat transfer gas to control a heat transfer time.

According to another aspect of the present embodiment, a multi-zone temperature control method by a heat transfer adjustment structure includes a step of installing a heat transfer adjustment structure between a heat source and a heat sink, a step of supplying a first heat transfer gas to a first inner space among multi-zones of the heat transfer adjustment structure; a step of supplying a second heat transfer gas to a second inner space among multi-zones of the heat transfer adjustment structure; a step of adjusting a pressure of the first heat transfer gas; a step of adjusting a pressure of the second heat transfer gas; a step of controlling a heat transfer time by changing a heat transfer amount between the heat source and the heat sink in accordance with the change in a pressure of the first heat transfer gas and the change in a pressure of the second heat transfer gas.

### Advantageous Effects

As described above, according to the exemplary embodiments of the present invention, it is possible to block or transfer heat which may be generated between a substrate and an electrostatic chuck and a base structure or between specific structures using the change in pressure of a heat transfer gas by installing a multi-zone heat transfer adjustment structure between a base structure in which a coolant is supplied and the substrate, in a substrate processing device to easily adjust the temperature of the substrate during the process or after the process.

Even if the effects are not explicitly mentioned here, the effects described in the following specification which are expected by the technical features of the present disclosure and their potential effects are handled as described in the specification of the present disclosure.

### DESCRIPTION OF THE DRAWINGS

FIG. 1 is a block diagram illustrating a substrate processing device according to an embodiment of the present invention.

FIGS. 2 to 3 are views illustrating a structure of a substrate processing device according to exemplary embodiments of the present invention.

FIGS. 4 to 13 are views illustrating a heat transfer adjustment structure of a substrate processing device according to exemplary embodiments of the present invention.

FIGS. 14 to 16 are views illustrating a heat transfer gas control device of a substrate processing device according to exemplary embodiments of the present invention.

FIGS. 17 and 18 are flowcharts illustrating a temperature control method according to other exemplary embodiments of the present invention.

### MODE FOR CARRYING OUT THE DISCLOSURE

Hereinafter, in the description of the present disclosure, a detailed description of the related known functions will be omitted if it is determined that the gist of the present disclosure may be unnecessarily blurred as it is obvious to those skilled in the art and some exemplary embodiments of the present disclosure will be described in detail with reference to exemplary drawings.

According to the exemplary embodiments, in a substrate processing device including an electrostatic chuck ESC used for a semiconductor process, such as etching and deposition, a heat transfer amount is changed using a pressure change of a heat transfer gas of a heat transfer adjustment structure to adjust a temperature of the substrate.

According to the exemplary embodiments, heat which may be generated between the substrate and the electrostatic chuck and the base structure or between specific structures may be transmitted or blocked by a heat transfer adjustment structure between a base structure including a coolant supplied by a chiller in the substrate processing device and the substrate and the electrostatic chuck or between the specific structures, during a semiconductor process in which plasma and a heater are used or after the process.

The heat transfer adjustment structure is manufactured or inserted in the substrate processing device or a single structure or between a plurality of structures to control heat transfer which may be generated due to the temperature difference between a heat source and a heat sink. The heat transfer adjustment structure is used at an extremely low temperature of −100° C. or lower, a low temperature of −100° C. or higher and 0° C. or lower, or a temperature of 0° C. or higher of the heat source or the heat sink.

The heat transfer adjustment structure may be applied to various technical fields in which the heat transfer adjustment between specific structures is required, in addition to the substrate processing device.

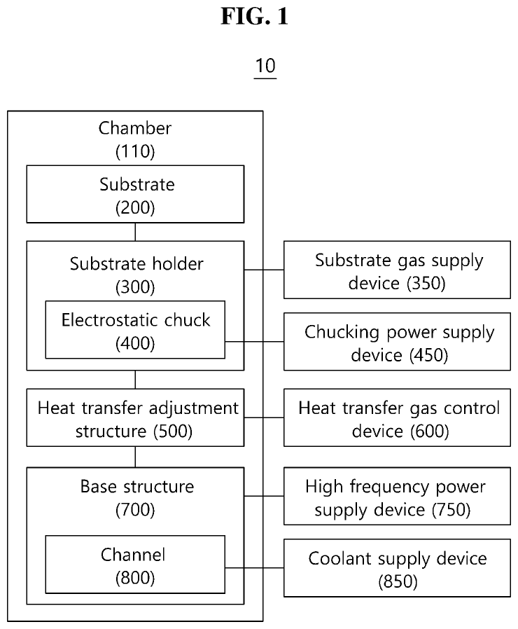

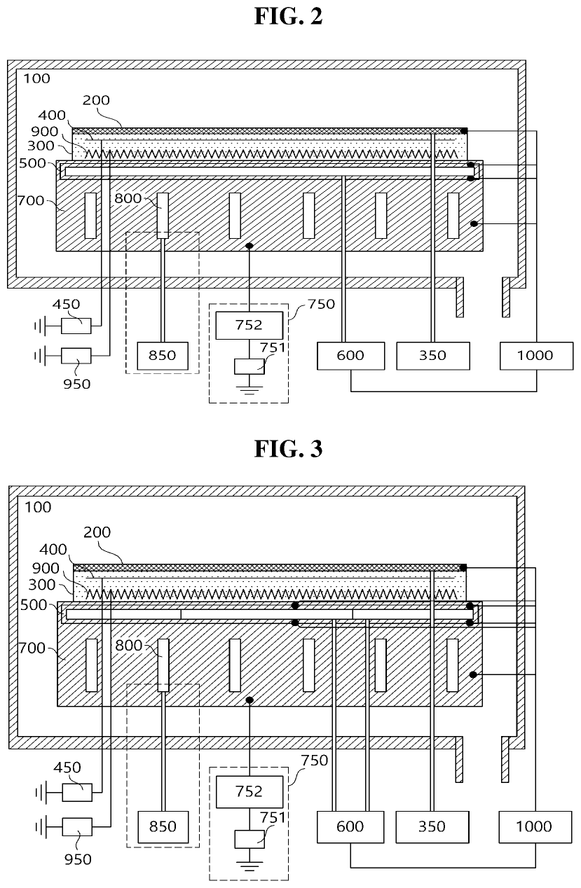

FIG. 1 is a block diagram illustrating a substrate processing device according to an embodiment of the present invention. FIG. 2 is a view illustrating a structure of a substrate processing device having a single heat transfer space according to an embodiment of the present invention. FIG. 3 is a view illustrating a structure of a substrate processing device having a multi-zone heat transfer space according to another embodiment of the present invention.

When the substrate processing device is described as an example, the substrate processing device 10 includes a substrate holder 300, a heat transfer adjustment structure 500, and a base structure 700.

The substrate processing device 10 is located in the chamber 100 and the inside of the chamber 100 is maintained in a vacuum state by an atmospheric pressure or a vacuum system.

In the substrate holder 300, an electrostatic chuck 400 which is located in the chamber and fixes the substrate using an electrostatic force is installed. The substrate gas supply device 350 is connected to the substrate holder and supplies gas to a rear surface of the substrate. A chucking power supply device 450 is connected to the electrostatic chuck and supplies a chucking power to the electrostatic chuck.

The substrate holder 300 includes a heat structure 900 which adjusts a temperature of the substrate. The substrate processing device 10 includes a heat power supply device 950 which supplies a heat power to the heat structure.

The heat transfer adjustment structure 500 is located between the substrate holder 300 and the base structure 700 and has a single inner space. The heat transfer adjustment structure 500 has a plurality of inner spaces. The heat transfer gas control device 600 is connected to the heat transfer adjustment structure and supplies the heat transfer gas.

The base structure 700 is located in the chamber and has a channel 800 formed therein. A high frequency power supply device 750 is connected to the base structure and supplies a high frequency power. A coolant supply device 850 is connected to the channel and supplies a coolant.

The electrostatic chuck generates an electric force (for example, a coulomb force and Johnsen-Rahbek force) in the space formed in the substrate to fix the position of the substrate. A substrate temperature and a temperature uniformity are controlled by a substrate rear surface gas supplied by the substrate gas supply device in the formed space.

The substrate rear surface gas supplied from the substrate gas supply device 350 is sprayed between the substrate holder 300 and the substrate to adjust heat transfer generated between the substrate holder 300 and the substrate. When there is no heat transfer adjustment structure 500, it is difficult to expect the substrate temperature rising effect of the substrate rear surface gas by the heater structure of the substrate holder 300 due to a coolant of a relatively low temperature of a low temperature of −100° C. or higher and 0° C. or lower or an extremely low temperature of −100° C. or lower supplied to the base structure 500. In contrast, when the heat transfer adjustment structure 500 is formed between the base structure 700 and the substrate holder 300, the heat transfer of the coolant of a relatively low temperature of a low temperature of −100° C. or higher and 0° C. or lower or an extremely low temperature of −100° C. or lower supplied to the base structure 500 and the substrate holder 300 is effectively controlled to increase the temperature of the substrate holder 300 and the substrate by the heater structure. For example, when the heat transfer space in the heat transfer adjustment structure is in a vacuum state, the base structure 700 and the substrate holder 300 is a vacuum insulation state with little heat transfer and heat generated in the structure is effectively transferred to the substrate.

The heat transfer gas of the heat transfer adjustment structure 500 controls a gas pressure in a wider range than the substrate rear surface gas. A desirable pressure of the substrate rear surface gas is approximately 1 Torr to 100 Torr and at a relatively high pressure, leakage of the substrate rear surface gas or separation of the substrate may be caused. The leakage of the substrate rear surface gas affects the plasma composition during the process to cause adverse effects on the process. In contrast, the heat transfer gas of the heat transfer adjustment structure may perform the process without causing the leakage of the heat transfer gas at a relatively low or high pressure from a vacuum of 10 m Torr or lower to 760 Torr or higher.

The substrate rear surface gas may be helium, nitrogen, or argon which are gases with thermal conductivity. The thermal conductivity of helium is the most excellent so that it is desirable to use helium.

The electrostatic chuck is mainly configured by dielectric materials and a chucking electrode is buried therein. A representative example of a dielectric material is Al₂O₃, doped-Al₂O₃, or AlN, and a volume resistivity of the dielectric material is 1 to 10 Ω·cm. The chucking electrode may be a mono-polar electrode or a bipolar electrode and may be implemented by a metal material (for example, Mo or W).

The chucking power supply device may be implemented by a filter, a direct current (DC) power supply device or an alternating current (AC) power supply device. For example, a voltage is generated in a space using a chucking power supply device in the space between an electrostatic chuck configured by a dielectric material in a volume resistivity range (<10¹³ Ω*cm) and a substrate located between the electrostatic chuck so that the position of the substrate is fixed onto the electrostatic chuck using the electrical force. The electrical force may be Johnsen-Rahbek force. The Johnsen-Rahbek force depends on the temperature of the electrostatic chuck so that when the temperature of the electrostatic chuck is changed, the force may be Johnson-Rahbeck force or a coulomb force. For example, the chucking power supply system g may be used to fix the electrostatic chuck configured by a dielectric material in a volume resistivity range (<10¹³ Ω*cm) and the position of the substrate located above the electrostatic chuck. The voltage is generated in the electrostatic chuck by the chucking power supply device so that the position of the substrate is fixed onto the electrostatic chuck using the electrical force. The electrical force may be a coulomb force. The coulomb force depends on the temperature of the electrostatic chuck so that when the temperature of the electrostatic chuck is changed, the force may be a coulomb force or Johnsen-Rahbek force.

A diameter of the substrate may be 300 mm or 200 mm and a diameter of the electrostatic chuck may be smaller than or equal to the diameter of the substrate. In addition to the chucking electrode, a substrate rear surface gas supply line (for example, a minute hole) may be provided in the electrostatic chuck. A surface roughness Ra of the electrostatic chuck may have a range of ≤0.3. The electrostatic chuck may be manufactured as one body with the heater structure.

The substrate gas supply device may be controlled by gas supply including a plurality of gas lines if necessary.

Coefficients of thermal expansion between the structures of the substrate processing device formed by dielectrics and metal materials are within ±50% and as the larger the difference, the smaller the impact due to the temperature change when the structures are coupled. For example, a coefficient of thermal expansion of a dielectric material Al₂O₃ of the electrostatic chuck is approximately 10*10⁻⁶/k and a coefficient of thermal expansion of a structure coupled to the dielectric material Al₂O₃ of the electrostatic chuck may have a value between 5*10⁻⁶/k to 15*10⁻⁶/k.

The heater structure may be used to control a temperature and the temperature uniformity of the substrate which is located in a fixed state by the electrostatic chuck. The heater structure is configured by a dielectric material and a heating electrode is buried in the dielectric material. The heating electrode buried to control the temperature and the temperature uniformity of the substrate may be one or plural and may have an appropriate heating electrode pattern. The dielectric material may be AlN and the heating electrode configuring material may be Si or W.

The heater power supply device may be implemented by a filter, a direct current (DC) power supply device or an alternating current (AC) power supply device. For example, when a power (P=I²R) is supplied to the heating electrode using the heater power supply device, the temperature and the temperature uniformity of the heater are controlled to control the temperature and the temperature uniformity of the substrate. The heater structure may be formed as one body with the electrostatic chuck.

The base structure is supplied with a power which is supplied from the RF power supply device including an external radio frequency (RF) power supply source via an RF matching system through a connector to be used as an electrode and generates the plasma, and is formed of a metal material. For example, the base structure may be metal such as aluminum or titanium alloy. The device may be applied to a reactive ion etching (RIE) reactor. A plurality of holes passes through the base structure. The plurality of holes allows the gas supply and temperature measurement equipment or a connector to pass through an upper portion of the base structure to be used to measure the temperature and supply the power. The connectors pass through the base structure to be connected to the structure such as an upper chucking electrode or a heater.

The base structure may be used to cool the electrostatic chuck or the substrate which is heated at a high temperature. When the substrate is exposed to the plasma during the process using the plasma, the temperature of the substrate may rise by the energy supplied to the substrate, such as ion bombardment or radiation. When the temperature of the substrate rises, the damage of the substrate and the ununiformity of the process result may be increased so that it is necessary to cool the substrate.

In the base structure, a channel through which the coolant flows for cooling may be formed. A coolant injected into the coolant channel of the base structure may be a coolant such as water, ethylene glycol, or liquid Teflon. Depending on the substrate, in order to form a low temperature of −100° C. or higher and 0° C. or lower, organic solvent such as hydrofluoroether or galden solution may be used and in order to form an extremely low temperature of −100° C. or lower, a coolant such as liquid nitrogen, liquid methane, or liquid argon may be used. At this time, the coolant may be supplied to the base structure using a coolant supply device including a chiller at the outside of the chamber.

The coolant may absorb not only the heat generated in the substrate but also heat generated by power applied to the base structure.

As a general configuration formed in the base structure, a configuration of a lift pin for unloading the substrate will not be illustrated.

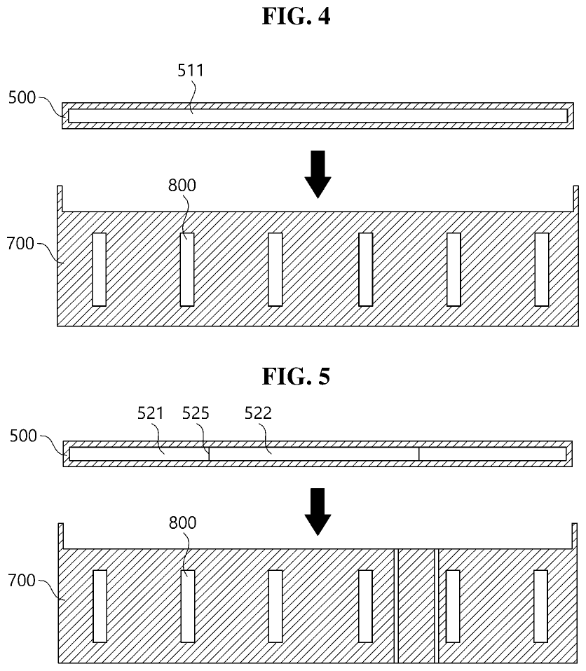

FIGS. 4 to 13 are views illustrating a heat transfer adjustment structure of a substrate processing device according to exemplary embodiments of the present invention.

FIG. 4 illustrates a structure in which a heat transfer adjustment structure having a single heat transfer space 511 is inserted into an insertion space of the heat transfer adjustment structure formed in the base structure 700. FIG. 5 illustrates a structure in which a heat transfer adjustment structure having multi-zone heat transfer spaces 521 and 522 by a separation wall 525 is inserted into an insertion space of the heat transfer adjustment structure formed in the base structure 700.

The heat transfer adjustment structure is manufactured separately from the substrate processing device to be inserted into the insertion space of the heat transfer adjustment structure formed in the base structure. The heat transfer adjustment structure and the base structure may be coupled by welding or mechanical coupling if necessary. The mechanical coupling may be coupling using a bolt. Rather than the method of inserting the heat transfer adjustment structure into the insertion space of the heat transfer adjustment structure formed in the base structure, the heat transfer adjustment structure may be manufactured as one body with the base structure.

If necessary, heat generated between the heat source and the heat sink is blocked or transferred through the heat transfer adjustment structure located in the substrate processing device and the heat transfer adjustment structure may easily control the temperature of the substrate during the process or after the process. For example, the temperature of the substrate may be changed from the room temperature to the extremely low temperature using the heat transfer adjustment structure.

The heat source may be a structure having a temperature higher than the heat sink. For example, the heat source may be a substrate which receives energy such as light or plasma to have a specific temperature or a temperature consistently rising, or a substrate after the process, or a heater. The heat sink may be a structure having a temperature lower than the heat source. For example, the heat sink may be a base structure including a coolant in the substrate processing device or a structure having a temperature lower than the heat source.

When the heat transfer space in the heat transfer adjustment structure located between the heat source and the heat sink is a vacuum state, heat flowing from a top plate to a bottom plate is relatively completely blocked by the vacuum insulation effect. For example, when a temperature of the heat source which is in contact with the top plate is a low temperature of −100° C. or higher and 0° or lower or a temperature of 0° C. or higher and a temperature of the heat sink which is in contact with the bottom plate is an invariable and extremely low temperature of −100° C. or lower, the temperature of the heat source which is in contact with the top plate may be a low temperature of −100° C. or higher and 0° or lower or a temperature of 0° or higher.

When the heat transfer space in the heat transfer adjustment structure located between the heat source and the heat sink is supplied with a heat transfer gas with a high pressure to have a sufficiently higher thermal conductivity of approximately 5 W/K or higher, the pressure rise of the heat transfer space makes heat transfer between the heat source and the heat sink relatively smooth by the thermal conductivity rising effect. For example, when a temperature of the heat sink which is in contact with the bottom plate is an invariable and extremely low temperature of −100° C. or lower, the temperature of the heat source which is in contact with the top plate is an extremely low temperature of −150° C. or lower, which is the same temperature as the heat sink.

The temperature of the heat source may be changed by the change in the heat transfer amount between the heat source and the heat sink according to the change in the pressure of the heat transfer gas of the heat transfer space in the heat transfer adjustment structure located between the heat source and the heat sink.

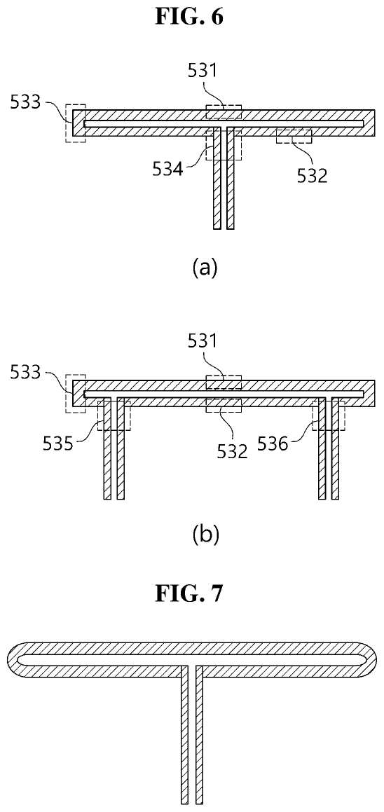

FIGS. 6 to 9 illustrate a structure of a heat transfer adjustment structure having a single heat transfer space 511.

FIG. 6 illustrates an example that the heat transfer adjustment structure has one heat transfer port and an example that the heat transfer adjustment structure has two or more heat transfer ports.

The heat transfer adjustment structure includes a top plate 531, a bottom plate 532, a side wall 533, a heat transfer space, and a heat transfer gas port 534. The heat transfer gas port includes a heat transfer gas supply port or a heat transfer gas discharge port and the gas may be supplied and discharged through a plurality of ports or one port. The top plate and the bottom plate have a thickness of 0.5 to 10 mm and are formed with a metal material. For example, the metal material may be aluminum stainless steel or other metal and an alloy thereof. However, depending on the material, the top plate and the bottom plate may be manufactured as a continuous one body with the heat source and the heat sink if necessary.

The top plate and the bottom plate of the heat transfer adjustment structure is located between the heat source and the heat sink which have specific temperatures. When the heat source and the heat sink which are in contact with the heat transfer adjustment structure have different temperatures and the heat transfer space has variable thermal conductivity and heat transfer coefficient, variable heat transfer may occur between the heat source and the heat sink. At this time, the smaller the thicknesses of the top plate and the bottom plate, the more the advantageous the heat transfer between the heat source and the heat sink.

The lower the surface roughness of the top plate and the bottom plate, the more the advantageous the heat transfer between the heat source and the heat sink. For example, when the heat transfer adjustment structure is manufactured, the surface roughness of the top plate and the bottom plate is controlled to be low by the polishing process.

The description about the side wall of the heat transfer adjustment structure and the heat transfer space structure is also applied to the case that one or a plurality of heat transfer gas ports 535 and 536 is connected to the heat transfer space.

FIG. 7 illustrates an oval structure of a side wall which connects the top plate and the bottom plate of the heat transfer adjustment structure. The top plate and the bottom plate are connected through the side wall and form the heat transfer space therein. The side wall separates the heat transfer space of the heat transfer adjustment structure from the external environment excluding the heat transfer gas port included in the heat transfer adjustment structure. The side wall may be a straight type which connect the top plate or may be a special type other than the straight type. For example, the side wall may be an oval type or may be formed by three ovals which are continuously connected.

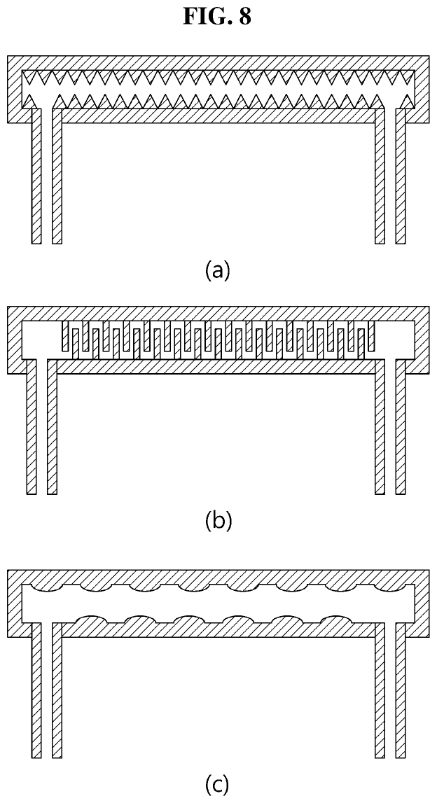

FIG. 8 illustrates various structures of a heat transfer adjustment structure having a spike structure, a fin structure, or an embossing structure of a heat transfer space in the heat transfer adjustment structure. A heat transfer space of the heat transfer adjustment structure has an interval of 3 to 3000 μm and desirably, 50 μm or smaller. At this time, the heat transfer space may be implemented as a spike structure, a fin structure, and an embossing structure to increase a contact area with the heat transfer gas, in addition to the flat structure. The increase in the contact area of the heat transfer space with the heat transfer gas increases the heat transfer amount in the heat transfer space to be advantageous to quickly control the heat transfer.

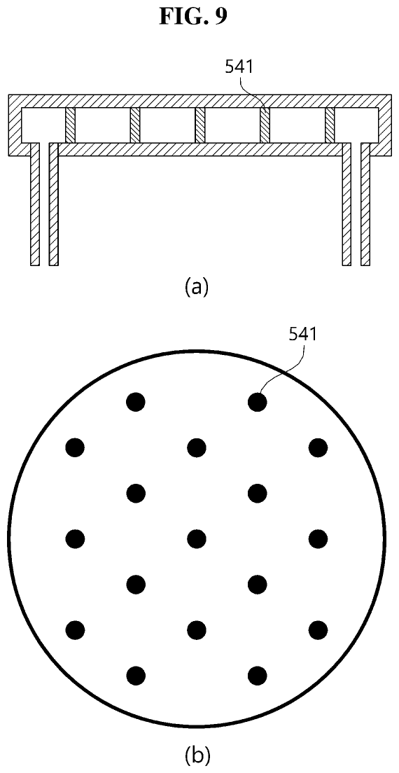

FIG. 9 illustrates internal support column placement of a heat transfer space in a heat transfer adjustment structure. In the heat transfer space, an internal support column 541 may be disposed to prevent the collapse of the heat transfer space due to a load of the heat source or the heat sink which may be disposed above the heat transfer adjustment structure. The internal support column is in contact with the top plate and the bottom plate and has various shapes such as a cylinder or a polygonal column. The internal support columns may be concentrically or straightly disposed and one column may support an area of approximately 2 cm². The internal support column may be manufactured by a metal material or a dielectric material. For example, a metal material or a dielectric material such as Al₂O₃ like the top plate and the bottom plate may be used.

The heat transfer adjustment structure may have parasitic heat transfer in addition to the heat transfer which is transferred by the heat transfer gas of the heat transfer space. The parasitic heat transfer includes heat conducted by the structural characteristic of the heat transfer adjustment structure, radiant heat generated between the top plate and the bottom plate, or radiant heat generated with the external environment. Rather than a variable heat transfer amount due to the heat transfer gas pressure between the top plate and the bottom plate, a fixed heat transfer amount may be obtained by the parasitic heat transfer. The parasitic heat transfer may have a heat transfer amount which is relatively smaller than the heat transfer amount which is transferred by the heat transfer gas of the heat transfer space. When the size of the internal support column between the top plate and the bottom plate is large and the number of internal support supports is small, the parasitic heat transfer amount may be reduced. When the length of the side wall which connects the top plate and the bottom plate is long and the side wall is thin, the parasitic heat transfer amount may be reduced.

The heat transfer space of the heat transfer adjustment structure may be supplied with the heat transfer gas having a thermal conductivity through the heat transfer gas port. The heat transfer gas port may be disposed on a top plate, a lower plate, and a side wall of the heat transfer adjustment structure. When the heat transfer gas port is disposed on the top plate or the bottom plate, the processing on the heat source or the heat sink which is in contact with the top plate or the bottom plate is necessary to pass the heat transfer gas line therethrough. The heat transfer gas port may be a metal material, and for example, aluminum stainless steel or other metal or an alloy thereof.

The heat transfer gas may be helium, nitrogen, or argon which are gases with thermal conductivity. The thermal conductivity of helium is the most excellent so that it is desirable to use helium. When the interval of the heat transfer spaces is constant, the rising of the pressure of the heat transfer gas in the heat transfer space may vary the heat transfer amount between the top plate and the bottom plate. In contrast, as the pressure of the heat transfer gas in the heat transfer space is low, the heat transfer amount between the top plate and the bottom plate is reduced. When the intervals of the heat transfer spaces are different, the heat transfer amounts of the heat transfer spaces may be different for every space.

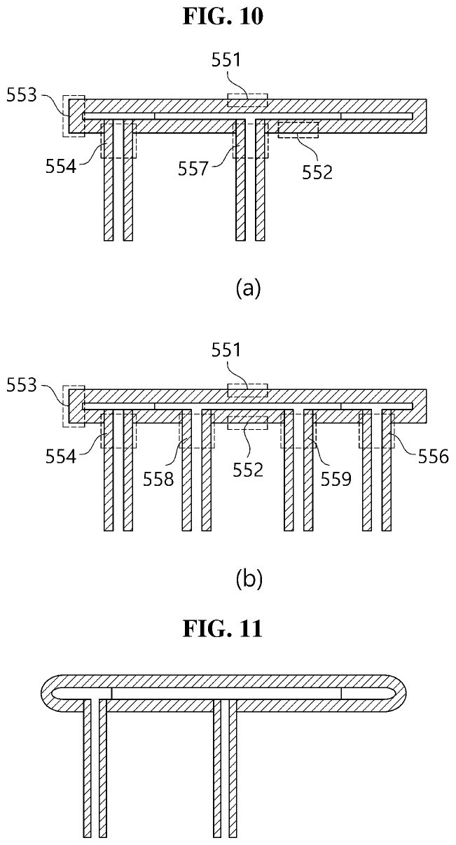

FIGS. 10 to 13 illustrate a structure of a heat transfer adjustment structure having a multi-zone heat transfer space.

FIG. 10 illustrates an example that the heat transfer adjustment structure has one heat transfer port and an example that the heat transfer adjustment structure has two or more heat transfer ports.

Referring to FIG. 10, the multi-zone heat transfer adjustment structure has a plurality of separated heat transfer spaces and each heat transfer space supplies and discharges the heat transfer gas using heat transfer gas ports 554 and 557 and adjusts the heat transfer amount of the multi-zone heat transfer adjustment structure by adjusting a heat transfer gas pressure of the heat transfer space. Supply gas ports 555 and 558 and discharge gas ports 556 and 559 may be connected to the multi-zones. For example, the change of the heat transfer gas pressure of a center heat transfer space and a side heat transfer space of the multi-zone heat transfer adjustment structure may adjust differently the heat transfer amounts of the heat source, the center and the side of the heat sink.

FIG. 11 illustrates an oval structure of a side wall which connects the top plate and the bottom plate of the heat transfer adjustment structure. The top plate and the bottom plate are connected through the side wall and form the multi-zone heat transfer space therein.

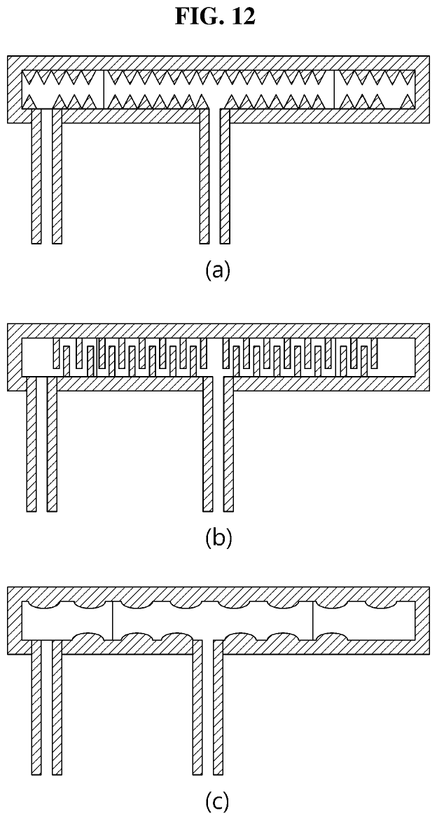

FIG. 12 illustrates various structures of a heat transfer adjustment structure having a spike structure, a fin structure, or an embossing structure of a heat transfer space in the heat transfer adjustment structure.

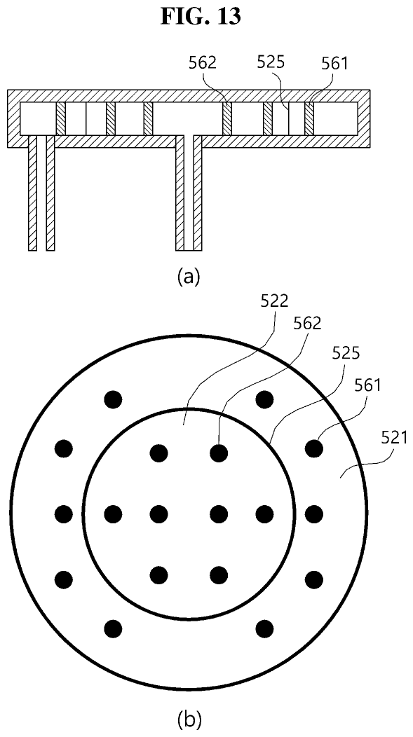

FIG. 13 illustrates internal support column placement of a heat transfer space in a heat transfer adjustment structure. In the heat transfer space, an internal support column may be disposed to prevent the collapse of the heat transfer space due to a load of the heat source or the heat sink which may be disposed above the heat transfer adjustment structure.

The heat transfer adjustment structure has a plurality of inner spaces by a top plate, a bottom plate, a side wall, and a separation wall and a heat transfer gas may flow in or out through a gas port which is connected to the top plate, the bottom plate, the side wall, or a combination thereof.

The heat transfer adjustment structure may be divided into a first inner space 521 and a second inner space 522 by the separation wall 525. The first inner space 521 and the second inner space 522 are divided into an outer circle and an inner circle. A first internal support column 561 is installed in the first inner space 521 and a second internal support column 562 is installed in the second inner space 522.

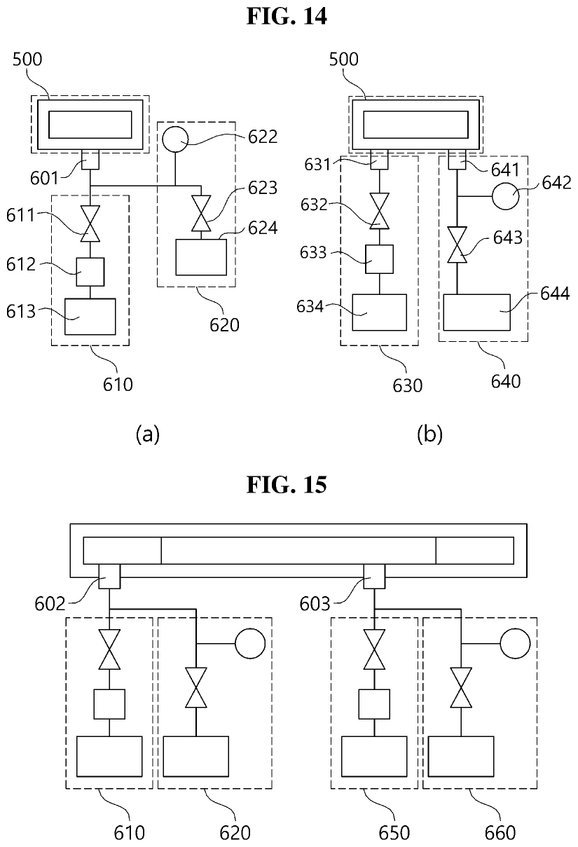

FIGS. 14 to 16 are views illustrating a heat transfer gas control device of a substrate processing device according to exemplary embodiments of the present invention.

The heat transfer gas control device includes a gas supply device and a gas discharge device.

The heat transfer gas supply and the gas discharge of the heat transfer adjustment structure is performed by one heat transfer gas port or two or a plurality of ports.

When the heat transfer adjustment structure has one heat transfer gas port, the gas supply pipe passes through the gas support device and the gas supply valve from the gas supply source and then branched to the gas discharge device through a branching point 601 and the heat transfer gas of the heat transfer space is supplied and discharged through one heat transfer gas port.

When the heat transfer adjustment structure has one gas port, the gas supply device 610 of the heat transfer adjustment structure supplies the heat transfer gas to the heat transfer space and the heat transfer gas supply device includes a gas supply pipe, a gas supply source 613, a gas control device 612, and a gas supply valve 611. The gas discharge device 620 of the heat transfer adjustment structure discharges the heat transfer gas of the heat transfer space and the discharge device includes a gas discharge pipe, a pressure gauge 622, a pressure adjustment valve 623, and a vacuum pump 624. When the pressure of the heat transfer adjustment gas in the heat transfer space is higher than a reference value, the heat transfer gas discharge device discharges the heat transfer gas.

When the heat transfer adjustment structure has a plurality of gas ports, in the heat transfer adjustment structure, the gas supply line 631 and the gas discharge line 641 may be separated and the gas supply device and the gas discharge device is separately connected through a plurality of ports, such as the supply port and the discharge port.

When the heat transfer adjustment structure has a plurality of gas ports, the gas supply device of the heat transfer adjustment structure supplies the heat transfer gas to the heat transfer space and the gas supply device includes a gas supply pipe, a gas supply source 634, a gas control device 633, and a gas supply valve 632. The gas discharge device of the heat transfer adjustment structure discharges the heat transfer gas of the heat transfer space and the discharge device includes a gas discharge pipe, a pressure gauge 642, a pressure adjustment valve 643, and a vacuum pump 644. When the pressure of the heat transfer adjustment gas in the heat transfer space is higher than a reference value, the heat transfer gas discharge device discharges the heat transfer adjustment gas.

The heat transfer gas supply device and the discharge device may be applied to the center heat transfer space and the side heat transfer space, respectively.

Referring to FIG. 15, the gas supply device 610 and the gas discharge device 620 are connected to the gas port 602 connected to the first inner space and the gas supply device 650 and the gas discharge device 660 are connected to the gas port 603 connected to the second inner space.

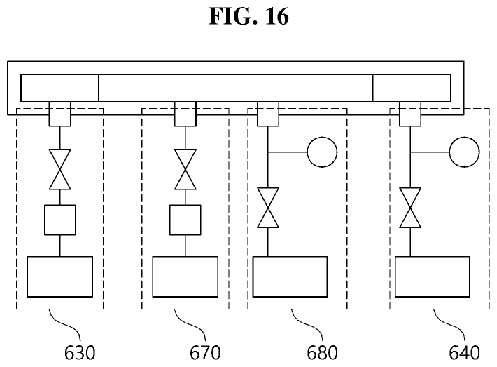

Referring to FIG. 16, the gas supply device 630 is connected to the gas supply port connected to the first inner space and the gas discharge device 640 is connected to the gas discharge port. Further, the gas supply device 670 is connected to the gas supply port connected to the second inner space and the gas discharge device 660 is connected to the gas discharge port.

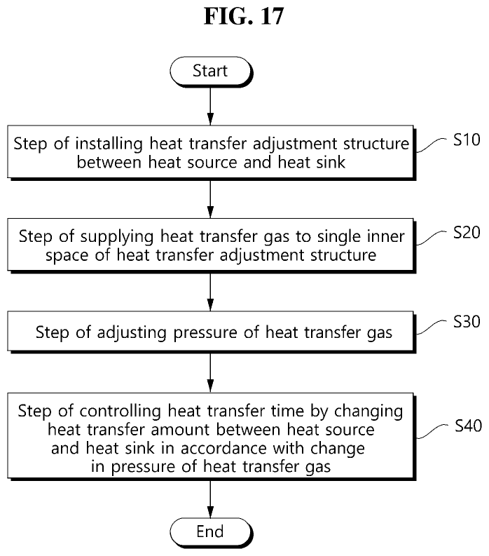

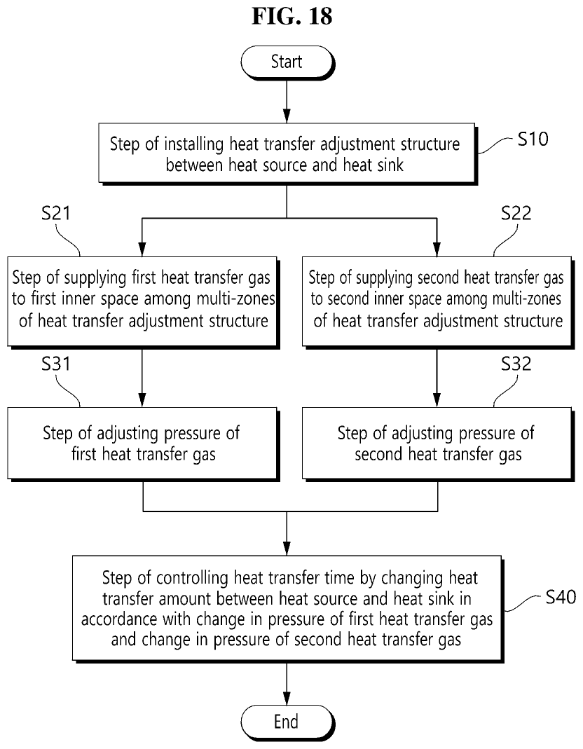

FIGS. 17 and 18 are flowcharts illustrating a temperature control method according to other exemplary embodiments of the present invention. The temperature control method is performed by the heat transfer adjustment structure.

Referring to FIG. 17, a temperature control method by a heat transfer adjustment structure includes a step S10 of installing a heat transfer adjustment structure between a heat source and a heat sink, a step S20 of supplying a heat transfer gas to a single inner space of the heat transfer adjustment structure, a step S30 of adjusting a pressure of the heat transfer gas, and a step S40 of controlling a heat transfer time by changing a heat transfer amount between the heat source and the heat sink in accordance with the change in a pressure of the heat transfer gas. Referring to the substrate processing device, the heat source corresponds to the holder and the heat sink correspond to the base structure.

Referring to FIG. 18, a multi-zone temperature control method by a heat transfer adjustment structure includes a step S10 of installing a heat transfer adjustment structure between a heat source and a heat sink, a step S21 of supplying a first heat transfer gas to a first inner space among multi-zones of the heat transfer adjustment structure, a step S22 of supplying a second heat transfer gas to a second inner space among multi-zones of the heat transfer adjustment structure, a step S31 of adjusting a pressure of the first heat transfer gas, a step S32 of adjusting a pressure of the second heat transfer gas, and a step of controlling a heat transfer time by changing a heat transfer amount between the heat source and the heat sink in accordance with the change in a pressure of the first heat transfer gas and the change in a pressure of the second heat transfer gas. Referring to the substrate processing device, the heat source corresponds to the holder and the heat sink correspond to the base structure.

Even though components included in the substrate processing device are separately illustrated in FIG. 1, the plurality of components are coupled to each other to be implemented by at least one module.

The substrate processing may be mounted in a computing device provided with a hardware element as a software, a hardware, or a combination thereof. The computing device may refer to various devices including all or some of a communication device for communicating with various devices and wired/wireless communication networks such as a communication modem, a memory which stores data for executing programs, and a microprocessor which executes programs to perform operations and commands.

The present embodiments are provided to explain the technical spirit of the present embodiment and the scope of the technical spirit of the present embodiment is not limited by these embodiments. The protection scope of the present embodiments should be interpreted based on the following appended claims and it should be appreciated that all technical spirits included within a range equivalent thereto are included in the protection scope of the present embodiments.

| | |
|---|---|
| 10: Substrate processing device | 100: Chamber |
| 200: Substrate | 300: Substrate holder |
| 350: Substrate gas supply device | 400: Electrostatic chuck |
| 450: Chucking power supply device | |
| 500: Heat transfer adjustment structure | |
| 600: Heat transfer gas control device | 700: Base structure |
| 750: High frequency power supply device | 800: Channel |
| 850: Coolant supply device | 900: Heat structure |
| 950: Heat power supply device | |
| 1000: Temperature measurement device | |

1. A substrate processing device, comprising:
a chamber
a substrate holder which is located in the chamber and has an electrostatic chuck which fixes a substrate using electrostatic force;
a base structure which is located in the chamber and has a channel formed therein;
a heat transfer adjustment structure which is located between the substrate holder and the base structure and has a plurality of inner spaces;
a substrate gas supply device which is connected to the substrate holder and supplies a gas to a substrate rear surface;
a chucking power supply device which is connected to the electrostatic chuck and supplies a chucking power to the electrostatic chuck;
a heat transfer gas control device which is connected to the heat transfer adjustment structure and supplies the heat transfer gas;
a high frequency power supply device which is connected to the base structure and supplies a high frequency power; and
a coolant supply device which is connected to the channel and supplies a coolant.

2. The substrate processing device of claim 1, wherein the substrate holder includes a heat structure which adjusts a temperature of the substrate and
the substrate processing device includes a heat power supply device which supplies a heat power to the heat structure.

3. The substrate processing device of claim 1, wherein the heat transfer adjustment structure has a plurality of inner spaces by a top plate, a bottom plate, a side wall, and a separation wall and a heat transfer gas flows in or out through a gas port which is connected to the top plate, the bottom plate, the side wall, or a combination thereof.

4. The substrate processing device of claim 3, wherein the heat transfer adjustment structure is divided into an inner circle and an outer circle by the separation wall.

5. The substrate processing device of claim 3, further comprising:
a temperature measurement device which is connected to the top plate of the heat transfer adjustment structure to measure a temperature of the top plate, is connected to the bottom plate of the heat transfer adjustment structure to measure a temperature of the bottom plate, and is connected to the base structure to measure a temperature of the base structure.

6. The substrate processing device of claim 5, wherein coefficients of thermal expansion between the heat transfer adjustment structure and the base structure are set to have a difference within ±50%.

7. The substrate processing device of claim 5, wherein the heat transfer gas control device communicates with the temperature measurement device to control the difference between the temperature of the top plate and the temperature of the bottom plate to be within a predetermined range.

8. The substrate processing device of claim 3, wherein the side surface of the heat transfer adjustment structure is formed to have a curved structure.

9. The substrate processing device of claim 3, further comprising:
a plurality of support columns between the top plate and the bottom plate of the heat transfer adjustment structure.

10. The substrate processing device of claim 3, wherein a bottom surface of the top plate and a top surface of the bottom plate of the heat transfer adjustment structure are formed to have a spike structure.

11. The substrate processing device of claim 3, wherein a bottom surface of the top plate and a top surface of the bottom plate of the heat transfer adjustment structure are formed to have a fin structure.

12. The substrate processing device of claim 3, wherein a bottom surface of the top plate and a top surface of the bottom plate of the heat transfer adjustment structure are formed to have an embossing structure.

13. The substrate processing device of claim 1, wherein the heat transfer gas control device supplies or discharges the heat transfer gas to the heat transfer adjustment structure through a single gas port according to a temporal separation manner.

14. The substrate processing device of claim 1, wherein the heat transfer gas control device supplies or discharges the heat transfer gas to the heat transfer adjustment structure through a plurality of gas ports which are separately installed according to a spatial separation manner.

15. The substrate processing device of claim 1, wherein the heat transfer gas control device adjusts a pressure of the heat transfer gas to control temperature change of the plurality of inner spaces of the heat transfer adjustment structure.

16. The substrate processing device of claim 15, wherein the heat transfer adjustment structure varies a heat transfer amount between the top plate and the bottom plate according to the change of the pressure of the heat transfer gas to control a heat transfer time.

17. A multi-zone temperature control method by a heat transfer adjustment structure, comprising:
a step of installing a heat transfer adjustment structure between a heat source and a heat sink;
a step of supplying a first heat transfer gas to a first inner space among multi-zones of the heat transfer adjustment structure;
a step of supplying a second heat transfer gas to a second inner space among multi-zones of the heat transfer adjustment structure;
a step of adjusting a pressure of the first heat transfer gas;
a step of adjusting a pressure of the second heat transfer gas; and
a step of controlling a heat transfer time by changing a heat transfer amount between the heat source and the heat sink in accordance with the change in a pressure of the first heat transfer gas and the change in a pressure of the second heat transfer gas.
